(19) United States
(12) Patent Application Publication
(10) Pub. No.: US 2009/0250095 A1
(43) Pub. Date: Oct. 8, 2009

(54) LOW-PROFILE SOLAR TRACKING MODULE

(76) Inventors: Brent Perry Thorley, Fountain Hills, AZ (US); Gregory David Thorley, Paradise Valley, AZ (US); David Harris Thorley, Fountain Hills, AZ (US)

Correspondence Address: WEISS & MOY PC, 4204 NORTH BROWN AVENUE, SCOTTSDALE, AZ, 85251, US

(21) Appl. No.: 12/418,458

(22) Filed: Apr. 3, 2009

Related U.S. Application Data
(60) Provisional application No. 61/123,108, filed on Apr. 5, 2008.

(51) Int. Cl. H01L 31/052

(52) U.S. Cl. 136/246

(57) ABSTRACT

An apparatus for distribution of light across a target area has at least one non-shadowing lens. The non-shadowing lens has a plurality of prisms wherein each prism provides an approximately uniform distribution of light across a defined area of the target area to reduce a shadowing effect. The apparatus may further have a tracking mechanism attached to the at least one non-shadowing lens for orienting the at least one non-shadowing lens towards a source of the light.

### FIELD OF THE INVENTION

The present application is related to U.S. Provisional Application having Ser. No. 61/123,108, filed Apr. 5, 2008 and entitled, “LOW-PROFILE SOLAR TRACKING MODULE”. The present patent application claims the benefit under 35 U.S.C. §119(e).

### FIELD OF THE INVENTION

This invention relates to solar energy and, more specifically, to a low-profile solar tracking apparatus that utilizes a non-shadowing lens for concentrating solar radiation and which provides a uniform light distribution across a target area of the solar panel.

### BACKGROUND OF THE INVENTION

Traditional solar photovoltaic (PV) panels must be angled high in order for them to optimally perform. The typical recommendation for a fixed PV panel installation is to mount the PV panel equivalent to the latitude, which in the United States typically ranges from 30 to 50 degrees from horizontal. Fixed panels should also face the location's maximum solar elevation, which is South for the Northern Hemisphere.

Many potential PV installation sites such as flat roofs on residences, carports, business buildings, and “big box” stores often have requirements that all mechanical equipment be hidden. Mechanical components generally include HVAC equipment in zoning laws and ordinances, but also include solar panels. Because of this requirement, the orientation of PV panel installations may be forced to be less than optimal, thereby further decreasing the rate of return of the PV panel.

Tracking the sun with a solar collector can provide far more efficiency than a fixed panel installation. Compared to fixed PV panels that are optimally mounted, a two-axis tracking system yields approximately 37% more power for the same number of solar cells. If stationary panels are installed relatively flat, a two-axis tracker can provide up to 56% more power with the same number of solar cells. The economic breakeven periods on solar PV installations are currently 10 to 20 years. These increases in power output can play a large factor in the feasibility of solar PV installations.

Current two-axis solar tracking systems are typically large. They are mounted on vertically cantilevered poles that extend 12 feet or more into the air. To prevent these systems from shading one another, they are spaced widely apart. The large, elevated panel areas are potentially exposed to high wind loads. As a result, all the components of these systems must be quite robust, and therefore expensive. This type of installation may work well for industrial power generation sites, but they are unwieldy for home or most commercial installations. Further, as previously stated, many potential PV installation sites such as flat roofs on residences, carports, business buildings, and “big box” stores often have requirements that all mechanical equipment be hidden. Thus, current two-axis solar tracking systems may be too large and bulky to satisfy these requirements.

With two-axis solar tracking systems, other design possibilities have emerged to increase the power output relative to the overall cost. One such possibility has been the addition of solar concentrators, whether they are through reflective panels or lenses. One particular type of lens that may be incorporated is a Fresnel lens. A Fresnel lens has a surface consisting of a concentric series of simple lens sections so that a thin lens with a short focal length and large diameters is possible. Fresnel lens can also be linear, or 2-dimensional, for concentrating sunlight to a band or line focus. Fresnel lenses can be found in a number of applications, including lighthouses, rear-projection televisions, and optical magnification sheets for reading.

When used for energy collection, the current art of Fresnel lenses has a significant weakness—any shadows cast upon them translate directly to the target area. Fresnel lenses, by their design, are a flat form of a convex lens with a single point of focus. Energy collection systems that use Fresnel lenses generally place the target, typically a photovoltaic cell or a pipe containing a recirculating fluid, in front of the lens' focal point to fully illuminate the target. If an obstruction shadows a Fresnel lens, that shadow will be directly projected to the target. A portion of the target will receive full illumination while another potentially receives none.

Non-uniform light on a photovoltaic target cell can significantly reduce its power output. This, in turn, can reduce the power output for an array of cells that is serially wired to the shadowed cell. At high light concentrations of 20 to 2000 suns, uneven illumination also can cause thermal stresses that result in cracking and premature failure of the target cells.

Economic and practical realities limit the roof or land space allotted to a single solar collector. Some grouping of collectors is required in most installations, and concomitant shadowing usually occurs. This is especially true with low-profile collectors where multiple small collectors are arrayed to substitute for a single high-profile collector. There are multiple solutions to the negative effects of shadowing, but most permit a decrease in energy production that is excessively disproportionate to the decrease in available light. The best solution would be to redistribute available light over an entire collector surface, which would minimize the deleterious effects while maintaining energy production.

For the large, utility-scale tracking systems that employ Fresnel lenses for concentrated photovoltaic, or CPV, systems, the shadowing issue is mitigated with installations on large plots of land where obstructions are eliminated. When one tracker begins to shade another, the trackers are often turned away from the sun due to this shadowing issue. When shadowing present from other trackers or terrestrial objects, these utility-scale trackers may be turned away from the sun for two hours after sunrise and before sunset.

Despite much discussion about solar power and its advantages, fixed panels are relatively inefficient. Existing two-axis tracking systems improve efficiency, but remain too heavy, expensive, and visible for most installations.

Therefore, a need existed to provide a system and method to overcome the above problem. The system and method would provide PV technologies, or other solar engines, configured in an efficient, low-profile, self-contained tracking device that greatly increases both the feasibility and desirability of many solar installations.

### SUMMARY OF THE INVENTION

An apparatus for distribution of light across a target area has at least one non-shadowing lens. The non-shadowing lens has a plurality of prisms wherein each prism provides an approximately uniform distribution of light across a defined area of the target area to reduce a shadowing effect.

An apparatus for converting solar energy to electrical energy has a plurality of solar collectors. A tracking mechanism is attached to the plurality of solar collectors for orienting the plurality of solar collectors towards a source of light. The tracking mechanism is a two-axis tracker comprising two separate forms: one has a primary axis on which internal gimbals rotate, wherein the internal gimbals support one of the plurality of solar collectors and a connecting link attached to each of the plurality of solar collectors keeps movement of each of the plurality of solar collectors parallel to one another. The other has separate rows, each supporting a plurality of solar collectors, mounted on a rotating circular frame. These pluralities of solar collectors are also kept parallel by connecting links.

A method of converting solar energy to electrical energy comprising: automatically progressively and collectively turning and tilting an array of non-shadowing lenses to maintain an essentially perpendicular relationship between rays of sunlight and the non-shadowing lenses, each of the non-shadowing lenses having a plurality of prisms wherein each prism provides an approximately uniform distribution of light across a target area to reduce a shadowing effect on a solar cell positioned below at least one of the non-shadowing lenses.

The present invention is best understood by reference to the following detailed description when read in conjunction with the accompanying drawings.

### BRIEF DESCRIPTION OF THE DRAWINGS

FIGS. 1A-1C shows examples of a prior art single focal point linear Fresnel lenses, the focal point being located beyond the target band;

FIG. 2 shows the prior art of a cross-sectioned circular Fresnel lens with exaggerated sized prisms;

FIG. 3 shows a cross-section of a square circular Fresnel lens illuminating a square target area as in accordance to prior techniques;

FIG. 4 is a diagrammatic representation of the parallel rows of troughs with Fresnel lenses;

FIG. 5 shows the current art of circular Fresnel and how a shadow is translated from the lens to the target area.

FIG. 6 shows examples of our invention in a Linear Non-Shadowing lens, and how each of the individual prisms are illuminating the entire target area.

FIG. 7 is a diagrammatic representation of the parallel rows of troughs with Non-Shadowing linear lenses.

FIGS. 8A-8B shows an example of our Non-Shadowing lens in a circular configuration.

FIG. 9 is this invention's circular lens demonstrating the lack of shadow on the target area.

FIG. 10 shows a variation of this invention's Non-Shadowing circular lens with a square target area.

FIG. 11 shows an example of the variation of the prisms as shown in FIG. 10 to accommodate a non-round target. The solid line represents the outline of the lens at a diagonal from corner-to-corner through the lens. The dashed line shows the outline across the middle of the lens. The changes in the curvature accommodate the change in target lengths.

FIG. 12 shows how a prism may be altered to vary the radiation distribution. The dark line is a simple arc. The upper curve (A) would increase the radiation intensity near the outside edges of the target. The second curve (B) would increase the radiation intensity at the center of the target. The lower curve (C) would tightly converge and flip the radiation profile, as well as concentrate more radiation to the target's right edge. The segment's shape may also be comprised of straight line segments.

FIG. 13 shows a repeating pattern of Fresnel or this invention's circular Non-Shadowing lenses for a single target area to further assist in enhancing a uniform radiation distribution on the target when shading occurs.

FIG. 14 is an example of this invention's Non-Shadowing lens using a repeating pattern of individual facets which are individually designed to illuminate the entire target area.

FIG. 15 is a domed lens example of this invention's Non-Shadowing lens with repeating individual facets.

FIG. 16 is a low-profile 2-axis carousel tracker that rotates on a circular frame where parallel rows, or louvers, are used for mounting photovoltaic cells or alternately a linear Non-Shadowing lens and photovoltaic cells.

FIG. 17 shows a carousel tracker on a pitched roof to illustrate that Azimuthal, or East-to-West, tracking may be clockwise, counterclockwise, both, or even both directions in a single day's tracking.

FIG. 18 shows a carousel tracker on a pitched roof where the Azimuthal tracking may be counterclockwise during the summer months.

FIG. 19 is a potential embodiment of using linear Non-Shadowing lenses in conjunction with a 2-axis carousel tracker where the tilt of the rows is controlled by a central linear actuator and where the rotation of the frame is performed by at least one motor driven wheel in three outer supports as shown in FIG. 20.

FIG. 20 shows the potential embodiment of the frame support assemblies for FIG. 19 that can feature a motorized wheel or idler wheel for the frame to rest and an opposing, spring loaded lockdown mechanism with its own idler wheel.

FIG. 21 is a potential embodiment of a 2-axis carousel tracker with a lower fixed circular frame that supports the upper u-shaped frame which supports the parallel collector rows comprised of linear Non-Shadowing lenses or three-dimensional Non-Shadowing lenses.

FIG. 22 shows a cross-section of FIG. 21 to illustrate the linear actuator and connecting link to control the tilt of the rows and to illustrate the wheels that ride on the fixed round lower frame.

FIG. 23 shows a magnified view of FIG. 22 illustrating the linear actuator and a motorized wheel assembly with a lockdown wheel assembly on the underside that locks the u-shaped frame onto the lower frame.

FIG. 24 is a potential embodiment of domed three-dimensional Non-Shadowing lenses on a 2-axis gimbal style tracker designed for concentrated photovoltaic, or CPV, typically in the range of 200 to 2000 suns onto a target area.

FIG. 25 is another view of FIG. 24 showing a tilt-controlling connection link between the collectors or pods and the other axis' motor casing and drive which allow for a full 180° plus range of motion in both axes.

FIG. 26 is a potential embodiment of a gimbal tracker using standard photovoltaic, or PV, modules that allows for solar tracking on flat-roof installations where there is a height limitation for mechanical equipment as dictated by building codes.

Common reference numerals are used throughout the drawings and detailed description to indicate like elements.

### DETAILED DESCRIPTION

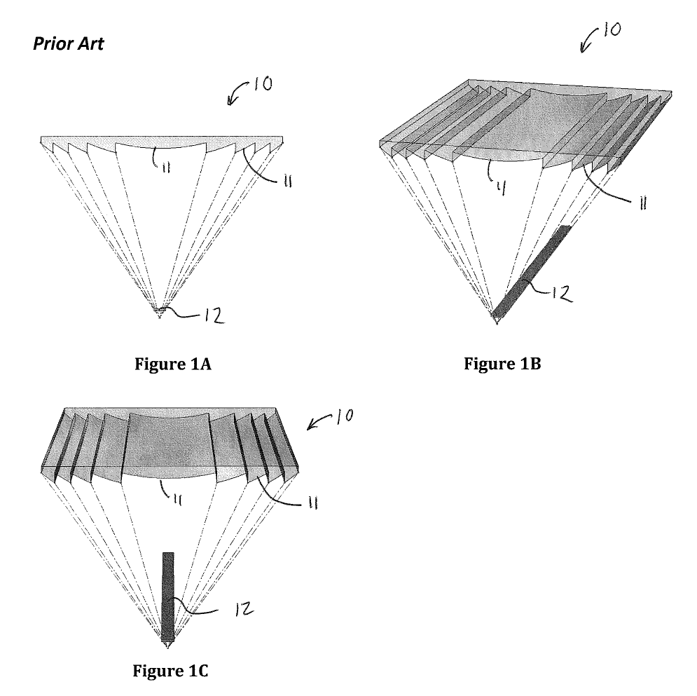

Referring now to FIGS. 1A-1C, a prior art single focal point linear Fresnel lens 10 is shown. The Fresnel lens 10 has a surface consisting of a series of simple lens sections 11 so that a thin lens with a short focal length and large diameters is possible. In the Fresnel lens 10, the surfaces of these lens sections 11 are designed to refract the light by collapsing the surface curvature of a conventional convex lens into a thin planar or curved sheet. As shown in FIG. 1, the surfaces of the prism side of the lens sections 11 approximate the curvature of a spherical or aspherical conventional lens. When looking at the surface geometry of adjacent lens sections 11, the end slope of one lens section 11 and the beginning slope of the next lens section 11 is parallel or nearly parallel.

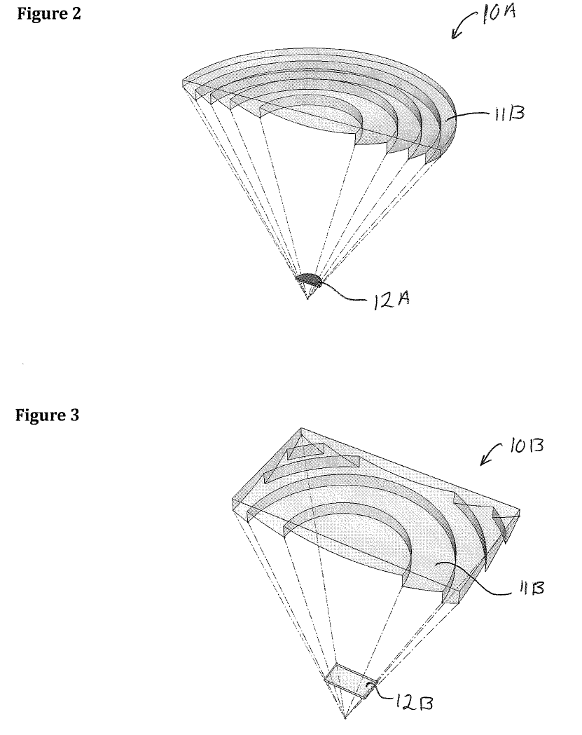

Referring to FIG. 2, one embodiment of a prior art Fresnel lens 10A is shown. In this embodiment, the Fresnel lens 10A is a circular, or 3-Dimensional, lens. The Fresnel lens 10A is used for illuminating a circular target area 12A. The Fresnel lens 10A is shown in cross-section with exaggerated sized prisms 11A. As can be seen, the bottom surfaces of each prism 11A are convex, and if were lined up end-to-end, would reveal a convex lens surface.

Referring to FIG. 3 another embodiment of a prior art Fresnel lens 10B is shown. The Fresnel lens 10B is similar to the Fresnel lens 10A. In the present embodiment, the Fresnel lens 10B is shown in cross-section and is of a square circular configuration for illuminating a square target area 12B.

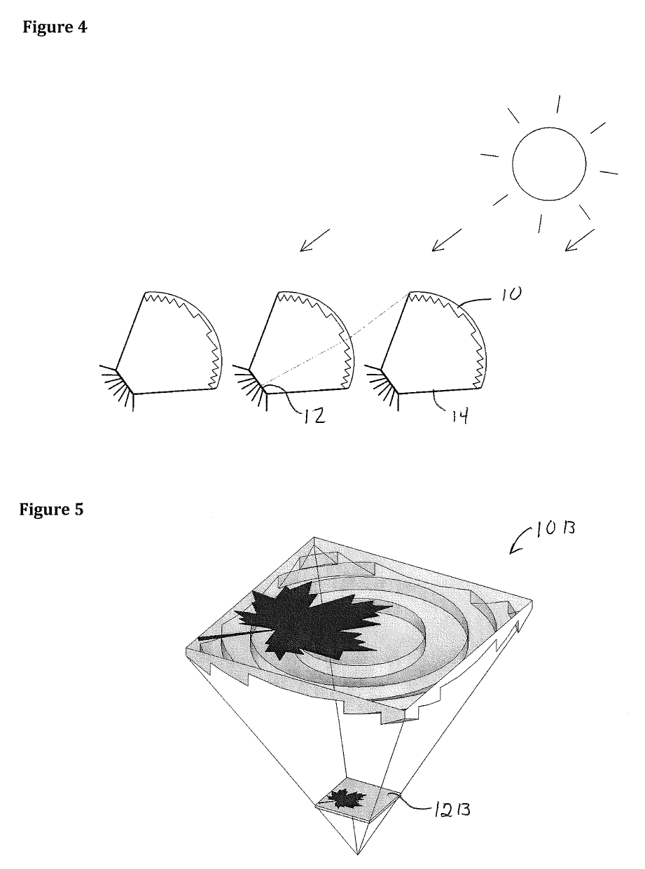

Referring now to FIG. 4, a row of prior art solar concentrating troughs 14, typically utilizing solar cells, is shown. The solar troughs, or rows, 14 are arranged in a parallel manner. Each solar trough 14 use a Fresnel lens 10 to increase the power output relative to the overall cost. As can be seen, current Fresnel lenses 10 have another significant weakness in that any shadows cast upon the Fresnel lens 10 translate directly to the target area 12. As shown in FIG. 4, as the sun gets lower in the sky, shadows are cast onto the target area 12 of adjacent solar trough 14. The shadows casted onto the target area 12 of adjacent solar troughs 14 can significantly reduce the power output for that adjacent solar trough 14, which, in turn, will reduce the power output for an entire wired series of solar concentrating troughs 14.

Referring now to FIG. 5, the effects of shadowing on the Fresnel lens 10B is shown in more detail. While FIG. 5 shows the Fresnel lens 10B having a square circular configuration, the shadowing effect is a weakness of all prior art Fresnel lenses 10. As shown in FIG. 5, any shadows cast upon the Fresnel lens 10B translates directly to the target area 12B.

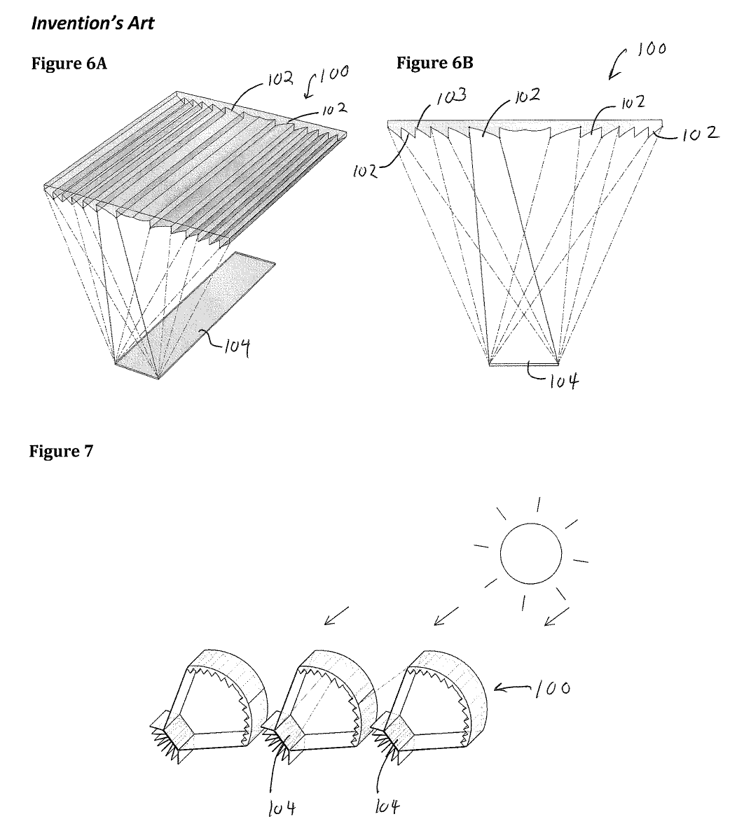

Referring now to FIGS. 6A-6B, a Non-Shadowing lens 100 of the present invention is shown. The non-shadowing lens 100 of the present invention also incorporates a periodic refractive structure of linear, concentric, or other geometric repeating prisms or facets 102 (hereinafter prisms 102). However, instead of collapsing the shape of a conventional convex lens, each prism 102 is its own lens and illuminates across the target area 104. A cursory inspection of this Non-Shadowing lens 100 in FIG. 6 reveals prisms 102 where the average surface slope appears similar to a Fresnel lens 10. However, a notable difference is that the surfaces of each prism 102 on the Non-Shadowing lens 100 will typically be concave, not convex, so that the light disperses from the relatively small cross-section of the prism 102 to the typically larger target area 104. The end slope of one prism 102 and the beginning slope of the next prism 102 are typically quite different.

Since a Fresnel lens 10 effectively behaves like a magnifying lens with a focal point, there is some flexibility in the target size and its distance from the lens. If a larger target area 12 is required, the Fresnel lens 10 can be positioned closer. If a smaller target area is required, the Fresnel lens 10 can be positioned further away. However, for the Non-Shadowing lens 100 of the present invention, the target area size and distance from the Non-Shadowing lens 100 must be defined. If the target 104 is positioned either in front of or behind the designated distance, the light will be dispersed to an area larger than the target 104.

One advantage of the Non-Shadowing lens 100 is that the highest concentration of light can be no higher than as designed. If for some reason the target 104 and its supporting structure is removed from a solar tracking apparatus, there is less risk of a highly concentrated line or point of light from overheating, melting, or igniting an object under the Non-Shadowing lens 100.

Since each prism 102 or set of prisms 102 is designed as a lens unto itself instead of collapsing a spherical or aspherical surface, the time required to design a Non-Shadowing lens is much more substantial, but is facilitated by modern Computer Aided Design (CAD) software packages and computer calculations.

The beginning steps to design a Non-Shadowing linear, or 2-Dimensional, lens and a 3-Dimensional lens are effectively the same. The first step is to decide on the target size 104, the level of concentration, and the dimensions of the Non-Shadowing lens 100 to be aimed at the sun. For a linear lens, the target size would be the width of the effective target band. To relate these three values, using an average lens transmittance, or efficiency, of approximately 85-92% is a good starting value.

The next step is to decide on the overall geometries of the Non-Shadowing lens 100. At this stage, drawing up a simple, oversized lens is very useful. This simple, oversized lens shape (hereinafter simplified lens) can be convex on both sides or planar on one side and convex on the other. Since the sunlight is a collimated beam of light, a simple biconvex or plano-convex lens will focus the light to a point. With a simplified lens, it is easier to calculate the theoretical transmittance of the Non-Shadowing lens 100 at various points across the Non-Shadowing lens 100.

At this point, the material or materials of the Non-Shadowing lens 100 is chosen. To calculate the transmittance and the curvatures of the simplified lens, the Index of Refraction between the lens' materials and air or vacuum is generally required. The material that maximizes the desired radiation profile based upon the spectral response of the photovoltaic cells or receptors is selected. The spectral response of many photovoltaic materials often is significant for infrared radiation, and especially for near infrared radiation. The material may also be selected for the frequencies it blocks, and which would be converted to unnecessary heat at the receptors. Lens materials comprise, but are not limited to, clear plastic, glass, clear silicone, or a combination.

Once the materials have been decided, a reference light frequency is chosen that takes into consideration the spectral response of the receptor, the solar spectral distribution, and the spectral transmittance for the lens materials. The corresponding Indices of Refraction at that frequency are used in further calculations. If desired, an achromatic lens, or a lens that minimizes the chromatic aberration, can be achieved in a non-shadowing lens 100 using more than one lens material with differing Indices of Refraction. To achieve a non-shadowing achromatic lens, overmolding a flexible lens material, such as clear silicone, onto a harder lens material such as glass or plastic could be considered.

Using the Index of Refraction and estimated lens efficiency, layout the simplified lens using Snell's law of refraction to achieve the desired concentration. Using the Fresnel equations for reflectance, calculate the combined transmittance into the simplified lens and out of the simplified lens. With these calculations, the direct relationship between the focal length and lens efficiency at the edges becomes quickly apparent. If the simplified lens is planar towards the collimated light of the sun, the distance between the simplified lens and the target area can become rather significant if one desires a high transmittance, or efficiency, from the simplified lens.

If one desires to minimize the focal length of the simplified lens and achieve a good transmittance of radiation, the ideal simplified lens layout equalizes the total reflectance in and the total reflectance out of the simplified lens' farthest edge. For example, say if the simplified lens should have an ideal transmittance of 85% at the furthest edge, the most efficient, shortest focal length lens should have a transmittance in and out of the square root of 85%, or approximately 92.2%. The resulting shape of the simplified lens will be one that is highly convex towards the sun and slightly convex towards the target. To illustrate, if the lens is to be 10 inches across, the radius of curvature of the sunward face should be approximately 6 inches and the radius of curvature of the face towards the target should be approximately 26 inches. A Fresnel lens with similar curvatures can be seen in FIG. 4. As an alternate to spherical sections, the simplified lens layouts can employee aspherical curves. This is a technique used for making lenses without spherical aberrations. Alternatively, a Fresnel or Non-Shadowing lens may have the prisms facing outward.

To construct the Non-Shadowing lens 100, the minimum and maximum lens thickness should be defined. The first prism 102, or segment, of the Non-Shadowing lens 100 may be designed anywhere in the Non-Shadowing lens 100. All the other prisms, however, will be designed subsequently to this first segment. In the Non-Shadowing lens 100 in FIGS. 6A-6B, the first prism 102 designed was on the outer edge. This first prism 102 is diverging the light evenly across the target. When looking at a cross-section as in FIG. 6B, the light from the left end of the prism 102 is aimed at the left edge of the target area 104. This angle can be readily calculated using Snell's law of refraction. This angle becomes the initial slope of the prism surface. The start of this prism 102 is at the minimum lens thickness.

An appropriate surface shape must then be calculated. The surface shape must meet two criteria: first, the right edge of the curve must equal the maximum thickness of the lens. Second, the angle tangent to the right side must be appropriate to refract light to the right edge of the target. When these criteria are met, the surface shape is determined. The width of the prism 102 is a resultant value.

Two methods can be used to determine the shape of the prism 102 surface. A concave curve shape, such a circular arc, can be used. Using iterative techniques, the curve size that meets the necessary criteria can be determined. A more exact method uses Snell's law to calculate the appropriate tangent angle at multiple points on the surface. The resulting surface can be defined using either computational or mathematical integration techniques.

To complete the first prism 102, a surface that extends from the right edge of the prism back to the minimum lens thickness must be added. This face of the prism is known as a draft 103. For the Non-Shadowing lens 100 in FIG. 6, the draft would simply be straight up or at a slight draft angle to ensure the part can be released from a mold. In the case of a curved front surface as shown in FIG. 7, the draft should be parallel to the light that will pass through the front surface of the Non-Shadowing lens 100.

The next prism 102 is now defined in a similar manner. The left point of the next prism 102 starts where the draft of the previous prism 102 intersects the minimum lens thickness. From this fixed point, the beginning angle of the arc can be readily computed so that the light will hit the left edge of the target area 104. As with the first prism 102, the surface is determined from the minimum to the maximum lens material thickness. This process is then repeated and more prisms 102 are defined.

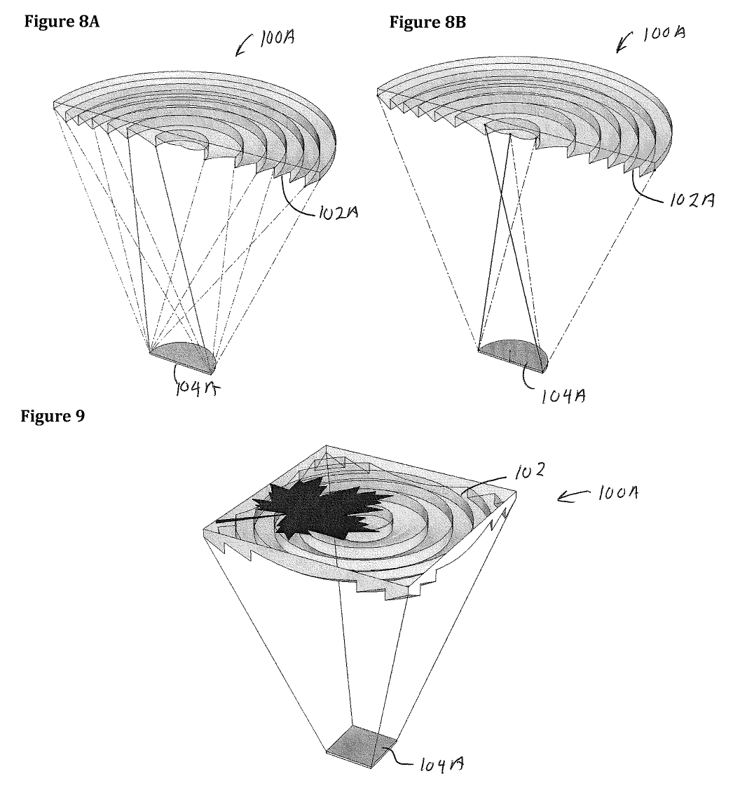

Optionally a prism 102 can be defined using a shape that differs from a concave arc as shown in FIGS. 8A-8B. A prism 102 can be defined using a convex arc where the left edge of the prism is defined to illuminate the right edge of the target, and the right edge of the prism 102 is defined to illuminate the left edge of the target 104. This effectively puts the prism's focal point in between the Non-Shadowing lens 100 and the target 104, and thereby tightly converging and therefore inverting the sunlight and the radiation distribution. This type of segment is required when the draft of a previous prism 102 will get in the way of a diverging prism 102, and occurs when the prisms 102 are directly over the target area in the Non-Shadowing lens 100.

For a linear Non-Shadowing lens 100, the prism 102 definition continues until the central plane of the Non-Shadowing lens 100 is reached. For a symmetrical linear lens 100, the prism pattern is mirrored over the center plane to create the right profile of the Non-Shadowing lens 100. This profile can then be extruded to create the linear Non-Shadowing lens 100.

When the Non-Shadowing lens 100 is molded, the sharp tips of the prism 102 can become rounded. In injection molding or compression molding, this can happen when air gets trapped and compressed in the mold and the plastic does not flow to create the sharp edge. To eliminate this issue, the profile of the prisms 102 can be extended further out towards the central plane of the Non-Shadowing lens 100. The draft of the prism 102 is changed as the tip is extended out along the prism's surface arc. The individual prisms 102 may only be extended so that they do not interfere with the light projected from the adjacent prism 102.

Optionally, sets of prisms 102 can be utilized to evenly illuminate the entire target area 104 where each prism 102 within a set only illuminates a prescribed portion of the target area 104. The set may consist of prisms 102 that are adjacent to one another or are distributed. To achieve the non-shadowing feature, more than one set would be required.

The Non-Shadowing lens 100 does not need to be symmetrical. If a linear lens is created only on a single side of its central plane, the orientation of the drafts should allow the Non-Shadowing lens 100 to be much more readily removed from a mold. A Non-Shadowing, asymmetrical lens can be created for situations where geometries of a structure, other physical constraints, or molding constraints would dictate the creation of such a lens.

As shown in FIG. 7, a linear Non-Shadowing lens 100 is two-dimensional, and therefore prevents shadowing on the target area 104 when the shadow is parallel to the linear Non-Shadowing lens 100 central plane. For example, the non-shading condition occurs when parallel rows of linear Non-Shadowing lens 100 aimed at the sun begin to block one another when the sun is low in the sky. As shown in FIG. 7, when the sun is low, the shadow from one row to the next does not induce a shadow thereby keeping the overall illumination relatively uniform.

The Non-Shadowing lenses 100 shown in FIG. 6 and FIG. 7 will only keep the concentrated radiation directly on a tightly defined target area 104 if a two-axis tracking system is employed. This would typically be for light concentration onto photovoltaic materials, but other types of receptors can be utilized. For example, Non-Shadowing lenses 100 may be used in Solar Thermal applications where the generated heat is collected and utilized. For Solar Thermal, a one-axis tracker can be employed with a Non-Shadowing lens 100. Since the Non-Shadowing lenses 100 will never concentrate the sunlight to a very high intensity line, the risk to the equipment is minimized.

Non-Shadowing lenses 100 may also incorporate diffractive optics. Diffractive optics, compared to non-diffractive optics lenses of similar focal length and aperture values, are usually smaller and lighter. In addition, diffractive optics lenses have superior chromatic aberration suppression characteristics; the chromatic aberration produced by diffractive optic lenses is opposite in direction to that produced by refractive lenses, and so the coupling of a diffractive element and a refractive element can almost cancel chromatic aberration. Diffractive optics may also be utilized in place of a refractive prism, when appropriate.

A Non-Shadowing lens 100 can also be utilized in systems that contain secondary reflectors, including reflective interior walls, reflective cones, or four-sided reflective cones. A Non-Shadowing lens 100 can also be utilized with secondary optics to allow for tracking error correction, to reduce the chromatic or spherical aberration, or for further focusing including focusing from the linear band to discrete areas of concentration.

Referring to FIGS. 8A-8B, another embodiment of a Non-Shadowing lens 100A in a circular configuration is shown. The design of a three-dimensional circular Non-Shadowing lens 100A begins in a similar method to a two-dimensional or linear Non-Shadowing lens 100. Instead of a focal plane that the profile of the Non-Shadowing lens 100 is extruded, the circular Non-Shadowing lens 100A is typically created around a central axis and the profile of the circular Non-Shadowing lens 100A is revolved about that central axis.

During the planning stage of a circular Non-Shadowing lens 100A, the final geometry must be carefully considered. Many circular prismatic lenses have a final shape that is square. When lying out the lens and weighing out the efficiency of the lens at the furthest prisms out, it is important to remember that the furthest prisms will be at the vertices of the square. The simple convex lens layout should be large enough to reach the vertices of the final square layout, and the cross-section profile should be diagonally between two opposing vertices of the square. The transmittance at various sections of the simplified lens layout should be carefully considered. Deciding upon the overall geometries upfront is especially important since Non-Shadowing lenses 100A have a fixed distance from the circular Non-Shadowing lens 100A to the target.

The process to construct a circular Non-Shadowing lens 100A is done on a prism 102A by prism 102A basis, just like the linear Non-Shadowing lens 100. However, when a circular Non-Shadowing lens is viewed in cross section, more light would appear to be directed to the edges of the target. This is to distribute the light evenly onto the target 104 as the prism 102A makes its way around the central axis. To visualize this using an analogy, imagine a bucket full of sand with a slit in the bottom. If you spin the bucket around an axis, a round pile of sand is formed. However, if the slit is a straight rectangular design where the sand pours out at an even rate throughout the slit, the pile of sand forms into a cone with an excessive amount of sand at the center. If the slit is a triangular shape where it is wide at the outer edge of the target and goes to a point at the axis of rotation, an even pile of sand is formed. The objective is to create a prism 102A with a surface profile that distributes the radiation with the highest concentration at the outside edges of the target 104 and then linearly decreases that radiation to zero at the center of the target 104. Hence the surface profile for each prism is not spherical or nearly spherical. It must be specifically calculated. The exact shape of the prism profile will be determined by the amount and type of curvature of other side of the circular Non-Shadowing lens 100A that would be typically facing the sun.

The prisms 102A for a circular Non-Shadowing lens 100A, like a linear Non-Shadowing lens 100, may diverge or tightly converge the sunlight towards the target 104 as shown in FIG. 8.

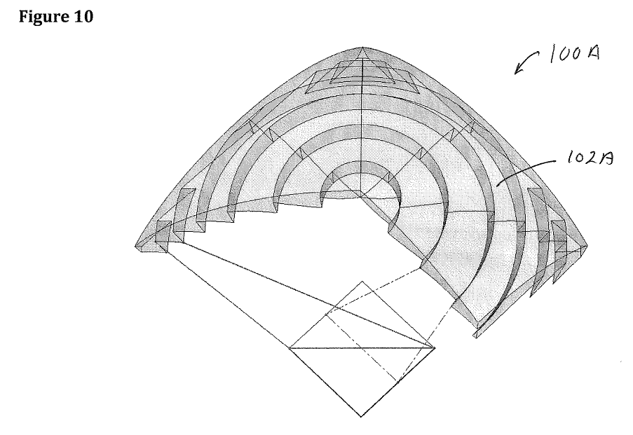

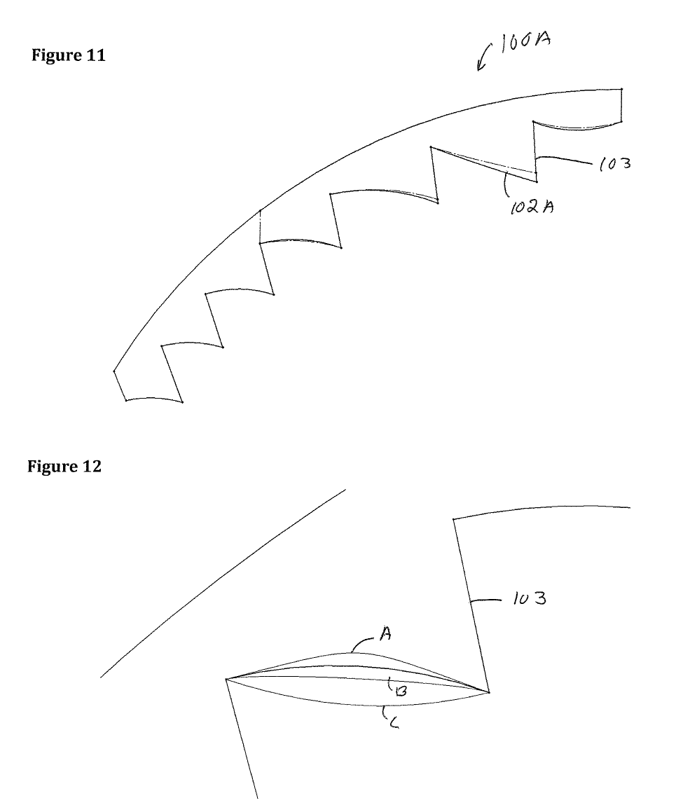

Referring now to FIGS. 9-11, for circular Non-Shadowing lenses 100A with a non-circular target 104A, such as a square, the effective size of the target 104A changes as the prism 102A travels about the central axis. If the target area 104A is 1 cm×1 cm, the size of the target 104A changes from 1 cm to √2, or 1.414 cm, at the diagonal between two vertices. See FIG. 10. The profile of the prism 102A is modified so that it will illuminate this larger square target area 104A. As the profile of the prism 102A is swept around the central axis, the profile gradually changes from the profile designed at 0° to the profile designed at 45°. See FIG. 10 and FIG. 11. When designing this prism 102A in CAD, the prism 102A is constructed by sweeping or lofting between the profiles designed at 0° and 45°. This one-eighth section of the circular Non-Shadowing lens 100A is then mirrored, and then that one-quarter section of the circular Non-Shadowing lens 100A is repeated four times to create the complete circular Non-Shadowing lens 100A. If the final outer shape of the circular Non-Shadowing lens 100A is square in this instance, the light will be completely uniform on the square target 104. This type of approach for varying the prism 102A profile can also be readily utilized for hexagonally shaped lenses and targets.

Referring now to FIG. 11, an example of the variation of the prisms 102A through its path around the lens' central axis to accommodate a non-round target 104 is shown. The solid line represents the outline of the circular Non-Shadowing lens 100A at a diagonal from corner-to-corner through the circular Non-Shadowing lens 100A. The dashed line shows the outline across the middle of the circular Non-Shadowing lens 100A. The changes in the curvature accommodate the change in target lengths.

Each prism 102A does not need to equally illuminate the whole target area 104. Please see FIG. 12. Prisms 102A may unequally illuminate the target 104 so that the final resulting illumination profile is uniform. This methodology would need to be employed if the outer shape of the circular Non-Shadowing lens 100A, say, is rectangular and the target 104 is circular.

A circular Non-Shadowing lens 100A prism 102A may also include ripples or distinct facets. These features may be utilized to sweep the light away from the central axis to the right and left of the target area 104.

The circular Non-Shadowing lens 100A may contain segments that are essentially linear, that are circular around a central axis, or may travel in a polygonal or other pattern around the circular Non-Shadowing lens 100A. The circular Non-Shadowing lens 100A may combine a combination of linear, circular, polygonal, oval or other patterns to assist in achieving high uniformity with the non-shadowing lens.

A Fresnel 10A or circular Non-Shadowing lens 100A does not necessarily require that the lens' and the target's central axes be one in the same. A Fresnel 10A or a circular Non-shadowing lens 100A can be offset from the target area 104, but still illuminate the target area 104. To do so requires carefully calculated variable prism profiles. The prior art has only created Fresnel lenses where the central axis of the lens and the target are coincident.

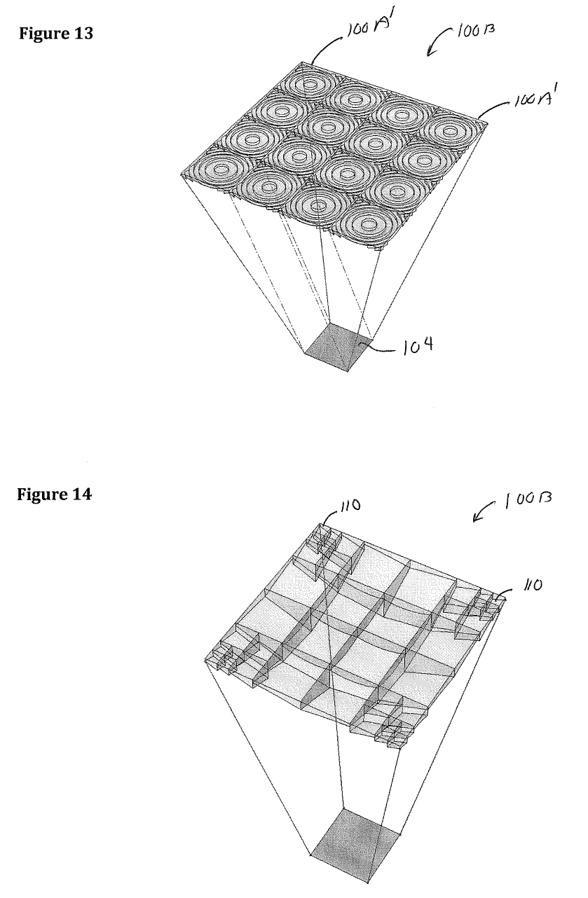

The rationale for creating an offset circular Fresnel 10A or Non-Shadowing lens 100A becomes quickly apparent in FIG. 13. FIG. 13 shows a Non-Shadowing lens 100B comprised of a repeating pattern of offset circular Non-Shadowing or Fresnel lenses 100A′ directed at a single target area. The Non-Shadowing lens 100B is used to assist in enhancing the radiation distribution on the target 104 when shading occurs. The reason for this type of design is to further enhance the Non-Shadowing capability of a circular prismatic lens. In a single axis circular Non-Shadowing lens 100A, as shown in FIG. 9, a shadow cast on a corner of the Non-Shadowing lens 100A does not cast a shadow, but the uniformity of the light hitting the target 104 will be diminished in a pattern that stretches from the corresponding shaded corner of the Non-Shadowing lens 100 across to the other corner of the Non-Shadowing lens 100. With a repeating pattern of offset circular lenses as shown in FIG. 13, this Non-Shadowing capability is further enhanced.

The embodiment shown in FIG. 13 shows a four-by-four pattern of sixteen individual circular Non-Shadowing lenses 100A. This is shown as an example and should not be seen as to limit the scope of the present invention. By looking at the pattern of circular elements, it can be seen that only three of the sixteen circular lens elements have to be designed. The others are either mirrored or patterned from the first three elements.

The repeating pattern shown in FIG. 13 can be comprised of circular prismatic lens elements being of the single or multiple focal point Fresnel type or of the circular Non-Shadowing lens 100A. Repeating pattern lenses may also be designed utilizing diffractive optics as discussed above.

Referring now to FIG. 14, another embodiment of Non-Shadowing lens 100B comprised of repeating patterns is shown. The repeating pattern in this embodiment is individual facets 110. Like FIG. 13, only ⅛^{th} of the facets 110 have to be individually designed to each fully illuminate the target area 104. The other facets 110 are mirrored or patterned to complete the lens design.

In FIG. 14, the facets 110 and the target area 104 are both square. This allows each element to illuminate the entire target area 104. The surface of each facet 110 is designed in a similar fashion to design of the linear and circular Non-Shadowing prisms 102, but instead of designing primarily two-dimensional profiles of the prism 102, the facets 110 typically require appropriate three-dimensional surfaces. The facets 110 can also be designed with concave surfaces to disperse the light from a relatively small facet 110 to the larger target, or be designed with convex surfaces to focus the solar radiation from a relatively large facet 110 to the target 104, or be designed with convex surfaces that tightly focus the radiation and effectively flip and invert it. As shown in FIG. 14, the facets 110 may be of differing sizes to assist in keeping the thickness of the Non-Shadowing lens 100B within the desired minimum and maximum thicknesses. Other geometric patterns may also be utilized, with the most likely other pattern being hexagonal for illuminating a hexagonal target.

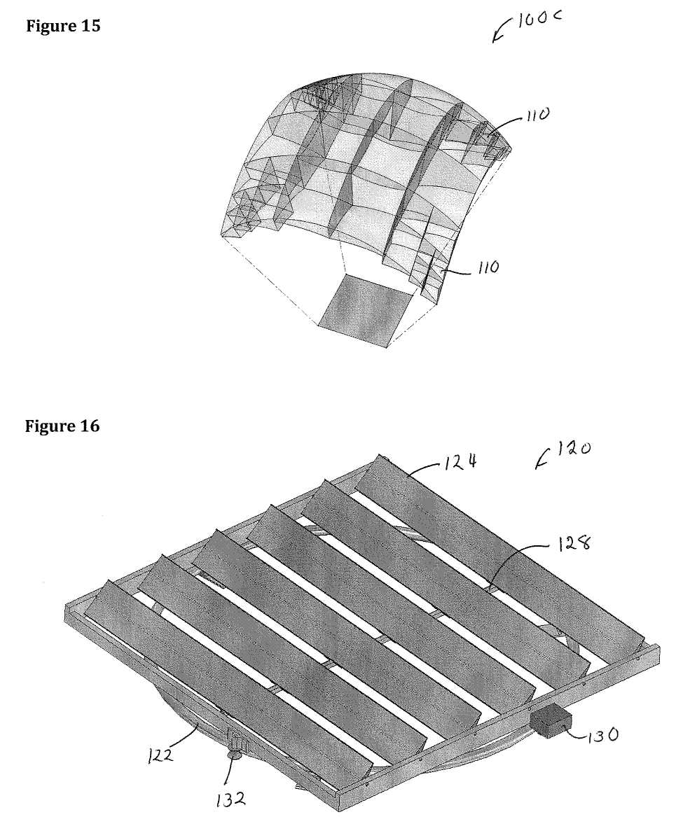

FIG. 15 is another example of the Non-Shadowing lens 100C comprised of repeating patterns. The Non-Shadowing lens 100C is a domed lens with repeating individual facets 110. The facets 110 in this embodiment are square to match the shape of the target area 104, but could also be hexagonal or other geometric pattern.

Referring now to FIG. 16, a low-profile 2-axis carousel tracker 120 is shown. The two-axis tracker 120 rotates on a circular frame 122 where multiple parallel rows, or louvers 124, are used for mounting photovoltaic cells or alternately a Non-Shadowing lens 100 and photovoltaic cells. The louvers 124 move so that they can be aimed towards the sun. Movement of these louvers 124, so that they can face the sun, comprises the first axis of this two-axis tracker, and provides the elevation tracking.

The parallel rows of louvers 124 are mounted on a frame 122. The frame 122 can then be rotated. The rotating frame 122 provides the East to West, or azimuthal tracking.

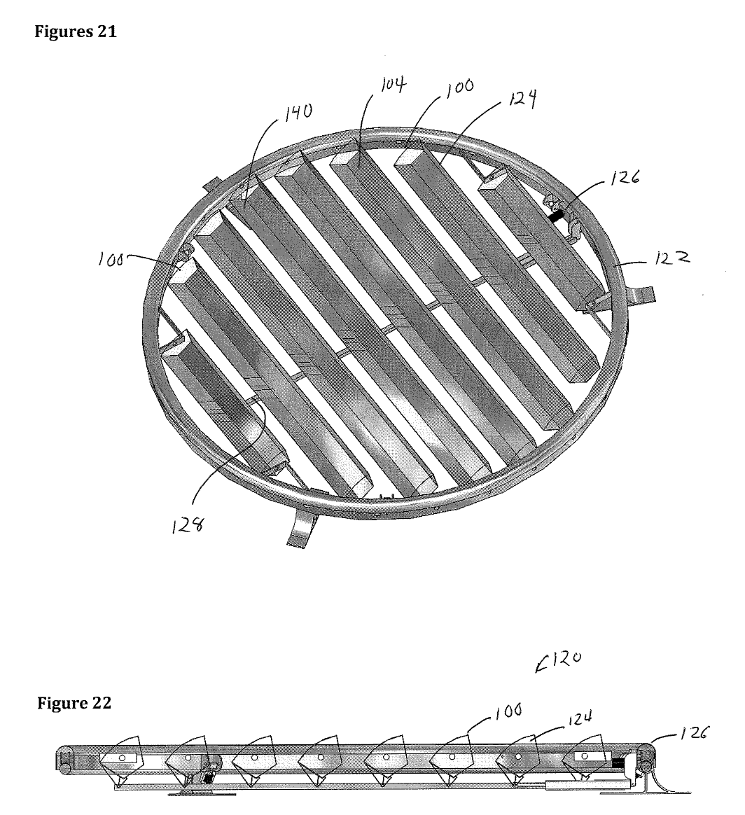

In the embodiments in FIG. 16 and FIG. 21, a single centrally located linear actuator 126 with a connecting rod 128 links all the louvers 124 and tilts the solar collectors, and a motorized gearhead 130 drives a guidewheel 132 around the fixed circular frame 122 which provides rotational, or azimuthal, positioning.

By the use of multiple spaced parallel louvers 124 and a rotating frame 122, full two-axis tracking can be accomplished in a package that may only be several inches tall. Due to the low-profile configuration of this tracker 120 and the fact it can be secured to a roof or weighted down at multiple points around the module, the structural and actuator requirements are greatly reduced as compared to existing trackers.

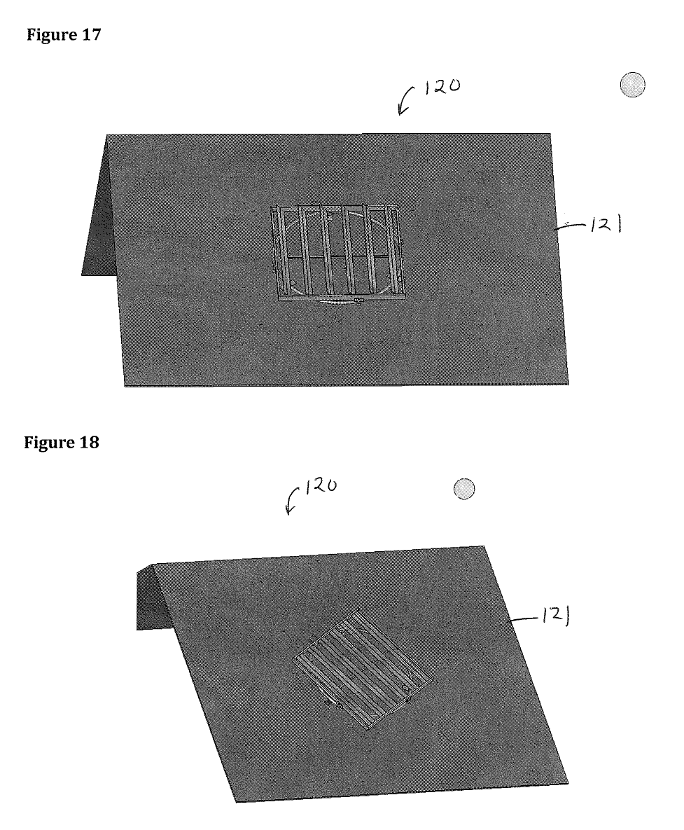

Referring now to FIGS. 17-18, a carousel tracker 120 is shown on a roof 121 to illustrate that Azimuthal, or East-to-West, tracking may be clockwise, counterclockwise, both, or even both directions in a single day's tracking. The setup of the carousel tracker 120 does not require a horizontal installation or any sort of vertical reference, such as a pole. As shown in FIG. 17, the carousel tracker 120 can be setup on even highly sloped roofs, and theoretically, even on vertical walls. The ability to be able to rotate from East to West in both clockwise and counterclockwise directions is critical for installations closer to the equator where the sun passes to the North in June and to the South in December. Tracking in clockwise and counterclockwise directions is also critical for installations on highly pitched roofs, as illustrated in FIG. 18.

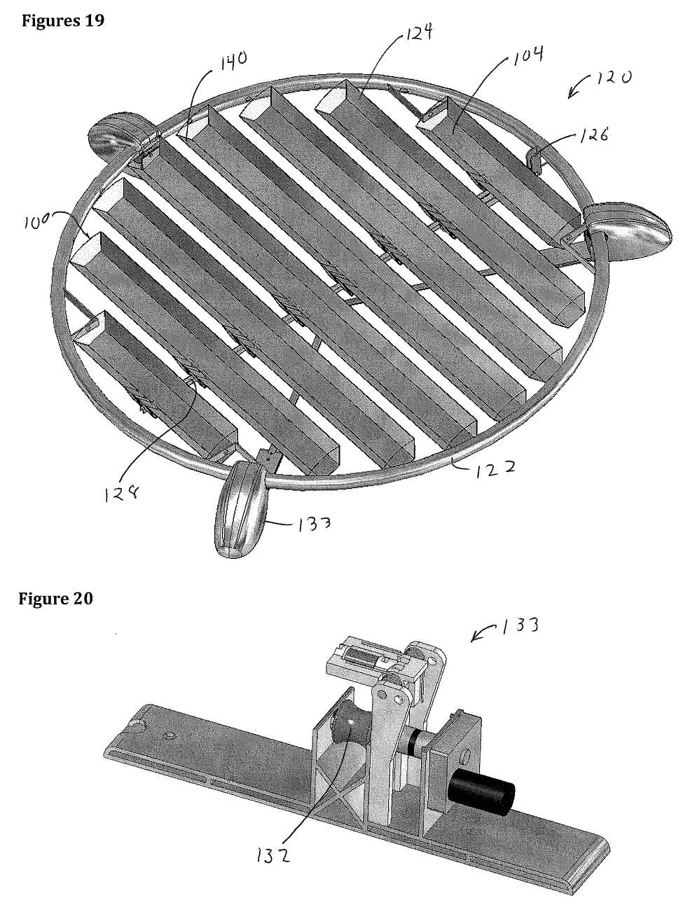

Referring to FIG. 19, a potential embodiment of using linear Non-Shadowing lenses 100 in conjunction with a 2-axis carousel tracker 120 is shown. The tilt of the louvers 124 is controlled by a central linear actuator 126 attached to a connecting rod 128 and linked to the louvers 124. The rotation of the frame 122 is performed by at least one motor driven wheel 132 in three outer supports 133 as shown in FIG. 20. Linear Non-Shadowing lenses 100 may be incorporated to significantly increase the power output per PV cell, as seen in FIG. 19 and FIG. 21. Any Non-Shadowing lenses 100 that are incorporated should be designed so that each prism of the Non-Shadowing lens 100 illuminates the entire target area 104, thereby allowing for power output even if the louvers 124 begin to shade one another. Alternatively, rows of three-dimensional Non-Shadowing lenses 100 may also be incorporated when concentrating to multiple discrete targets rather than a band of PV cells. Other solar engine designs, including chemical or thermal, may be able to be incorporated into this low-profile multiple row carousel 120 design if solar concentration is required.

A low-profile carousel tracker 120, as discussed above, would also have the advantage of decreased structural and weight requirements. This would apply to both the device and its' base support which would be anchored to a roof or the ground. Manufacturing and installation costs would be greatly decreased.

Important aesthetic advantages are also obtained from a low-profile design. Aesthetics are significant in the overall value of a home or building. A tracker 120 could be mounted on the roof of an existing building without the modules being seen from neighboring buildings or the street. Other “invisible” installations would be possible with minor architectural modifications.

To keep the cost of such a tracker 120 low, the design should utilize lower cost methods of manufacturing, such as extrusions, to create the louvers 124 and the frame 122.

A tracker 120 may contain secondary reflectors 140, including reflective interior walls, reflective cones, or four-sided reflective cones. A tracker 120 can also be utilized with secondary optics to allow for tracking error correction, to reduce the chromatic or spherical aberration, or for further focusing including focusing from the linear band to discrete areas of concentration.

The tracker 120 may incorporate logic to prevent twisting of any cables running from the rotating frame 122 to the mounts. If the tracker 120 rotates clockwise (CW) that day to perform the azimuthal tracking from East to West, then the tracker 120 would return to the East by rotating counterclockwise (CCW). Likewise, if the tracker 120 rotates CCW that day to perform the azimuthal tracking from East to West, then the tracker 120 would return to the East by rotating CW. The logic may further be used to handle retrograde tracking conditions. E.g., the tracker 120 starts out tracking CW, and then has to reverse to track CCW for the rest of the day. Retrograde tracking can result from installations on sloped roofs, such as shown in FIG. 18.

A power supply may used for powering the tracking motors, tracking sensors, and logic. The power supply may be provided externally to the tracker 120 or by an on-board power system with backup, or both.

The tracker 120 can be controlled either by wired or wireless communication devices. Communication with the tracker 120 can be achieved via the power leads going to or coming from the tracking modules.

A covering lens on the rows, or troughs, may be designed such that each the Non-Shadowing lens 100 would illuminate the entire target area 104. Therefore, if the rows partially shade each other, the illuminated Non-Shadowing lens 100 would distribute the remaining light equally over the target area 104. This would allow for power generation even when the elevation of the sun is low.

The tracker 120 may incorporate two or more banks of PV cells. These banks may be wired in parallel or in series by the installer for either battery backup or grid-tie systems.

With the possibility of incorporating of solar concentration such as the Non-Shadowing lenses 100, the additional heat can quickly become an issue for PV cells, and thereby decreasing their power output. By the use of extruded aluminum louvers 124 with heat sink fins, PV cells can maintain lower operating temperatures than non-concentrated PV cells sandwiched between glass and/or plastic sheets. With heat sink fins, or radiators, PV cells can run cooler even with a three-to-one concentration versus typical PV panels in a normal, roof mounted installation. And by keeping the resulting temperatures low, such a module would be safe for commercial or residential installations.

Referring to FIG. 21-23, another potential embodiment of using linear Non-Shadowing lenses 100 in conjunction with a 2-axis carousel tracker 120 is shown. FIG. 21 is a potential embodiment of a 2-axis carousel tracker 120 with a lower fixed circular frame 122 that supports the upper u-shaped frame which supports the parallel collector rows comprised of linear Non-Shadowing lenses 100 or three-dimensional Non-Shadowing lenses.

Referring now to FIG. 22, a cross-section of FIG. 21 is shown. FIG. 22 is shown to illustrate the linear actuator 126 and connecting link to control the tilt of the rows and to illustrate the wheels that ride on the fixed round lower frame 122.

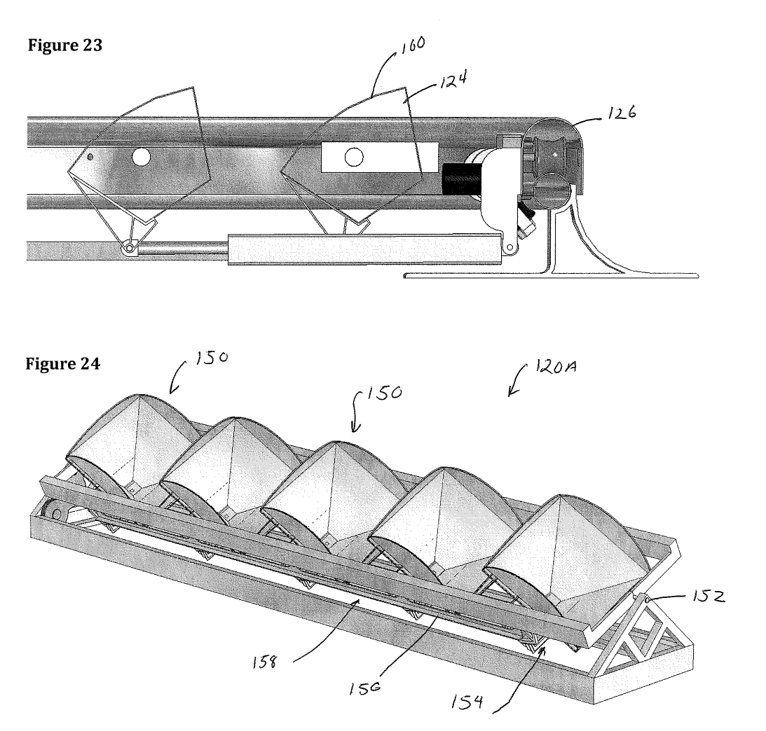

FIG. 23 shows a magnified view of FIG. 22 illustrating the linear actuator and a motorized wheel assembly with a lockdown wheel assembly on the underside that locks the u-shaped frame onto the lower frame.

Referring now to FIGS. 24-26, a two-axis gimbal-style solar tracker 120A is shown. Each tracker 120A is comprised of multiple collectors 150 that can be aimed towards the sun. The tracker 120A comprises a primary axis 152 on which internal gimbals 154 rotate. The internal gimbal 154 is comprise of a frame 156 and supports the collector 150. Each collector 150 is effectively another internal gimbal 154, but the collectors 150 motion on the internal frame 156 are kept parallel to one another by a connecting link 158.

If this tracker 120A is placed in a North-South installation, the primary axis 152 that supports the internal gimbal frame 156 would control the East to West tracking. The secondary axes 160 that support the individual collectors 150 would primarily provide the concomitant North to South tracking.

An individual tracker 120A of this type, installed appropriately, could track the sun from sunset to sunrise without any shadows being cast onto any of the collectors.

For the tracker 120A shown in FIG. 26 with PV modules, or panels, the tilt on the secondary axes 160 can be reduced in the winter months so that no shading occurs. If required, the tracker 120A may incorporate sensors or logic so that the modules will not shade one another. Likewise, the primary axis tilt for this same tracker 120A can be reduced near sunset and sunrise to prevent shading from terrestrial objects such as parapet walls or from adjacent trackers 120A.

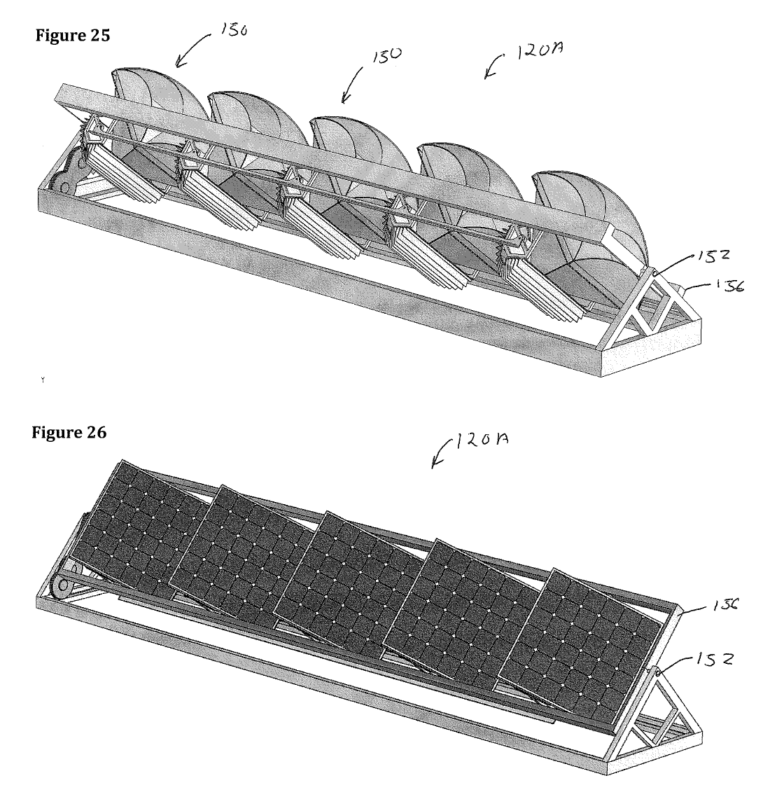

For the sunlight concentrating tracker 120A shown in FIGS. 24 and 25, a three-dimensional Non-Shadowing lens 100 truly makes this type of low-profile tracker 120A feasible. With a Non-Shadowing lens 100, this tracker 120A can be used from sunrise to sunset without the fear of partially shading or shadowing the rather delicate photovoltaic material when the remaining part of the cell is being hit with typically 200 to 2000 suns worth of radiation. High temperature differentials can result in stresses within the cell which can lead to premature cell failure.

The individual collectors 150 in FIGS. 24 and 25 can also be closely spaced on the internal gimbal due to the three-dimensional Non-Shadowing lenses 100. In the winter months and assuming a North-South alignment during installation, the collectors 150 could definitely shade one another, especially near or at solar noon. The three-dimensional Non-Shadowing lens 100, for the same reasons as stated before, is required for tightly spaced horizontally arranged CPV collectors.

For multiple trackers 120A, the spacing between them can be optimized according to the end user's wishes for either high collection density or optimal efficiency. The greater the East-West spacing between North-South aligned trackers, more of the day's sunlight will be available to each tracker 120A and thereby optimizing the individual tracker efficiency. The closer they are spaced, the more of the day's sunlight will be captured for a given area.

The tracker 120A does not necessarily require installation in a North-South alignment or on a flat surface. Each axis is designed for over 180° range of motion, and therefore the tracker 120A can be installed in a large variety of orientations. With the use of a family of accelerometers known as inclinometers, installation conditions can be quite varied and the initial setup and calibration of a tracker 120A is greatly simplified.

The different embodiments of the tracker 102 may rely on an accurate internal clock and applied astronomical algorithms to provide basic positioning. To do this, the tracker's exact longitude and latitude could be entered at installation. To provide more exact positioning, movement could be modulated using two approaches: The first approach is to use an array of photoelectric sensors and logic circuitry. The array would have a center tube with a photoelectric sensor at its base. If the center sensor is not illuminated, and the tube casts a shadow, the logic circuits would guide the positioning motors such that the arrays have proper orientation. A variant of this would be to project a solar image via a “pinhole” onto an imaging (CMOS or CCD) chip. If the brightest spot were off center, the logic circuitry would control the positioning motors appropriately. The imaging chip would also be able to detect the intensity of the available solar radiation.

The second approach would be to have the tilt angle quantified by inclinometers, and the rotational angle measured (against magnetic North) via magnetometers. The logic circuitry would provide feedback control to the positioning motors. This approach would require in-field calibration at installation.

As higher concentrations are used, more exact positioning is required. A combination of both approaches may be necessary.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

What is claimed is:

1. An apparatus for distribution of light across a target area comprising:
at least one non-shadowing lens having a plurality of prisms wherein each prism provides an approximately uniform distribution of light across a defined area to reduce a shadowing effect.

2. An apparatus in accordance with claim 1, wherein each of the plurality of prisms provides an approximately uniform distribution of light across a defined target area to reduce a shadowing effect.

3. An apparatus in accordance with claim 1, wherein the plurality of prisms form a plurality of sets of prisms, individual prisms in each of the plurality of sets of prisms illuminates a prescribed portion of a defined target area.

4. An apparatus in accordance with claim 2 wherein the non-shadowing lens is a linear non-shadowing lens.

5. An apparatus in accordance with claim 4 wherein the linear non-shadowing lens comprises a plurality of prisms, wherein each prism is a lens and illuminates an approximately uniform distribution of light across a target area.

6. An apparatus in accordance with claim 1, further comprising a plurality of non-shadowing lens, each non-shadowing lens having a plurality of prisms wherein each prism provides an approximately uniform distribution of light across a target area to reduce a shadowing effect.

7. An apparatus in accordance with claim 1, wherein the non-shadowing lens is a three-dimensional non-shadowing lens.

8. An apparatus in accordance with claim 1, wherein the non-shadowing lens is a three-dimensional circular non-shadowing lens, having a plurality of prisms, wherein each prism is formed around a central axis of the circular non-shadowing lens.

9. An apparatus in accordance with claim 8, wherein a surface profile for a prism is aspherical, and specifically calculated for each prism.

10. An apparatus in accordance with claim 8, wherein three-dimensional non-shadowing lens is offset from the defined area, wherein a central axis of the three-dimensional non-shadowing lens and a central axis of the desired area are dissimilar.

11. An apparatus in accordance with claim 1, further comprising a plurality of three-dimensional circular non-shadowing lens.

12. An apparatus in accordance with claim 1, further comprising a plurality of three-dimensional non-shadowing lens, wherein each three-dimensional non-shadowing lens has a plurality of repeating element lenses.

13. An apparatus in accordance with claim 1 further comprising a tracking mechanism attached to the at least one non-shadowing lens for orienting at least one non-shadowing lens towards a source of the light.

14. An apparatus in accordance with claim 13, wherein the tracking mechanism is a two-axis tracker comprising:
a frame having the at least one non-shadowing lens mounted thereon, the frame rotating one of clockwise or counterclockwise to approximately match a movement of the light source;
an actuator coupled to at least one louver, the louver supporting the at least one non-shadowing lens, the actuator moving the louvers so the at least one non-shadowing lens is approximately perpendicular to the light source.

15. An apparatus in accordance with claim 13, wherein the tracking mechanism is a two-axis tracker comprising:
a primary axis on which an internal gimbal rotates, wherein the internal gimbal supports the at least one non-shadowing lens; and
a connecting link attached to each of the at least one non-shadowing lens, to keep movement of each of the at least one non-shadowing lens parallel to one another.

16. An apparatus for converting solar energy to electrical energy comprising:
a plurality of solar collectors; and
a tracking mechanism attached to the plurality of solar collectors for orienting the plurality of solar collectors towards a source of light, wherein the tracking mechanism is a two-axis tracker comprising:
a primary axis on which at least one internal gimbal rotates, wherein the internal gimbal supports one of the plurality of solar collectors; and
means attached to each of the plurality of solar collectors for keeping movement of each of the plurality of solar collectors parallel to one another.

17. An apparatus in accordance with claim 16, further comprising at least one non-shadowing lens positioned above an individual solar collector, each non-shadowing lens having a plurality of prisms wherein each prism provides an approximately uniform distribution of light across a desired area to reduce a shadowing effect on the individual solar collector.

18. An apparatus in accordance with claim 17, wherein the at least one non-shadowing lens is a linear non-shadowing lens comprising a plurality of prisms, wherein each prism is a lens and illuminates an approximately uniform distribution of light across a target area.

19. An apparatus in accordance with claim 17, wherein the at least one non-shadowing lens is a three-dimensional non-shadowing lens.

20. An apparatus in accordance with claim 17, wherein the non-shadowing lens is a three-dimensional circular non-shadowing lens, having a plurality of prisms, wherein each prism is formed around a central axis of the circular non-shadowing lens.

21. An apparatus in accordance with claim 19, wherein three-dimensional non-shadowing lens is offset from the defined area, wherein a central axis of the three-dimensional non-shadowing lens and a central axis of the desired area are dissimilar.

22. A method of converting solar energy to electrical energy comprising: automatically progressively and collectively turning and tilting an array of non-shadowing lenses to maintain an essentially perpendicular relationship between rays of sunlight and the non-shadowing lenses, each of the non-shadowing lenses having a plurality of prisms wherein each prism provides an approximately uniform distribution of light across a target area to reduce a shadowing effect on a solar cell positioned below at least one of the non-shadowing lenses.

23. The method of claim 22 wherein each prism is a lens and illuminates an approximately uniform distribution of light across a target area.

24. An apparatus in accordance with claim 1, wherein the each prism provides an approximately uniform distribution of non-visible electromagnetic radiation light across a defined area to reduce a shadowing effect.

25. An apparatus in accordance with claim 1, further comprising a plurality of non-shadowing lens, each non-shadowing lens having a plurality of facets wherein each facet provides an approximately uniform distribution of light across a target area of the solar cell to reduce a shadowing effect on the solar cell.

26. An apparatus for distribution of light across a target area comprising:
at least one lens having a plurality of prisms wherein the at least one lens is a plurality of three-dimensional lenses, each lens of the plurality of three-dimensional lenses having a repeating pattern of prismatic lenses that act in conjunction to provide a non-shadowing effect.

27. An apparatus in accordance with claim 16, wherein the means is one of a connecting link or a drive mechanism to keep the movement of each of the plurality of solar collectors parallel to one another.
